(19) United States
(12) Patent Application Publication
(10) Pub. No.: US 2026/0006742 A1
(43) Pub. Date: Jan. 1, 2026

(54) MULTI-DIRECTIONAL HEATSINK COOLING SYSTEM

(71) Applicant: INTERNATIONAL BUSINESS MACHINES CORPORATION, ARMONK, NY (US)

(72) Inventors: Milnes P. David, New Paltz, NY (US); Philipp K. Buchling Rego, Wappingers Falls, NY (US); Sadegh Khalili, Poughkeepsie, NY (US)

(21) Appl. No.: 18/757,596

(22) Filed: Jun. 28, 2024

(51) Int. Cl. H05K 7/20

(52) U.S. Cl. CPC H05K 7/20154; H05K 7/20145; H05K 7/20209; H05K 7/20409; H05K 7/20445

(57) ABSTRACT

A multi-directional heatsink cooling system for cooling a device including a heatsink base in a first plane. The heatsink base is connected to a device requiring cooling. A plurality of heatsink fins attach to the heatsink base in a perpendicular or parallel orientation to the first plane. The plurality of heatsink fins are arranged to accept external cooling in multiple directions. A plurality of heat pipes extend through the plurality of heatsink fins. The plurality of heat pipes are connected to the heatsink base. Two or more air diverters, each air diverter associated with cooling the plurality of heatsink fins in a single air path of a plurality of air paths. Each air path is associated with exactly one of the multiple directions of the heatsink fins and thereby cool the plurality of heatsink fins.

### FIELD OF THE INVENTION

The present invention relates generally to a multi-directional heatsink cooling system and more particularly to a multi-directional heatsink cooling system to facilitate improved cooling in an electronic device.

### BACKGROUND

Presently disclosed embodiments relate to cooling of electronic devices. Heat is the enemy of electronic devices, as it causes increased component wear, can lead to computer errors, and leads to irreversible damages. Numerous solutions have presented themselves in the past to cooling of electronic devices, such as fans, liquid cooling systems, etc. but even these solutions may not present sufficient cooling capabilities in the realm of modern high-performance electronics, which may consume a comparably large amount of electricity and generate a large amount of heat, leading to the problems mentioned, and eventually failure of the electronic device.

Thus, a need presents itself for an improved heatsink cooling system for cooling of electronic devices.

### SUMMARY

Embodiments of the present invention are related to a multi-directional heatsink cooling system for cooling a device. The multi-directional heatsink cooling system includes a heatsink base in a first plane, the heatsink base connected to a device requiring cooling. A plurality of heatsink fins attach to the heatsink base in a perpendicular or parallel orientation to the first plane. The plurality of heatsink fins are arranged to accept external cooling in multiple directions. A plurality of heat pipes extend through the plurality of heatsink fins. The plurality of heat pipes are connected to the heatsink base. Also present are two or more air diverters, with each air diverter associated with cooling the plurality of heatsink fins in a single air path of a plurality of air paths. Each air path is associated with exactly one of the multiple directions of the heatsink fins to thereby cool the plurality of heatsink fins.

In an alternative aspect of the present invention, embodiments relate to an alternative multi-directional heatsink cooling system for cooling a device. The alternative multi-directional heatsink includes a heatsink base in a first plane. The heatsink base connected to a device requiring cooling. The plurality of heatsink fins are attached to the heatsink base in a perpendicular or parallel orientation to the first plane. The plurality of heatsink fins are arranged to accept external cooling in multiple directions. A plurality of heat pipes extend through the plurality of heatsink fins. The plurality of heat pipes are connected to the heatsink base. Also present are two or more air diverters. Each air diverter is associated with cooling the plurality of heatsink fins in a single air path of a plurality of air paths. Each air path is associated with exactly one of the multiple directions of the heatsink fins. Each of the plurality of heatsink fins is formed such that a plenum is present in each of the heatsink fins, and when the plurality of heatsink fins are stacked a greater plenum is formed via conjunction of the plenums present in each of the plurality of heatsink fins. The greater plenum allows air directed along each air path to exit the plurality of heatsink fins via the greater plenum and thereby cool the plurality of heatsink fins.

In another alternative aspect of the present invention, embodiments relate to a multi-directional heatsink cooling system for cooling a device. The multi-directional heatsink includes a heatsink base in a first plane. The heatsink base is connected to a device requiring cooling. A plurality of heatsink fins are attached to the heatsink base in a perpendicular or parallel orientation to the first plane. The plurality of heatsink fins are arranged to accept external cooling in multiple directions. A plurality of heat pipes extend through the plurality of heatsink fins. The plurality of heat pipes are connected to the heatsink base. Also present are two or more air diverters. Each air diverter is associated with cooling the plurality of heatsink fins in a single air path of a plurality of air paths, each air path associated with exactly one of the multiple directions. The plurality of heatsink fins are formed in two or more different shapes to allow the plurality of heatsink fins to separate air from different air paths in order to enhance cooling of the heatsink fins.

### BRIEF DESCRIPTION OF THE DRAWINGS

FIG. 1 displays a perspective diagram of a multi-directional heatsink 100, in accordance with an embodiment of the present invention.

FIG. 2 displays an exploded view of a plurality of heatsink fins 120, 125 in accordance with an embodiment of the invention.

FIG. 3 displays a perspective diagram of an electronic device 300 with installed multi-directional heatsinks 100, in accordance with an embodiment of the present invention.

FIG. 4 displays a schematic diagram of an electronic device 400 with an installed multi-directional heatsink 100 cooled by airpaths 440, 460, in accordance with an embodiment of the invention.

FIG. 5 displays a flowchart 500 showing temperature controls of fans in accordance with an embodiment of the invention.

FIG. 6 displays a perspective view of a plurality of heatsink fins 620, 625 in accordance with an alternative embodiment of the invention.

FIG. 7 displays an exploded view of a plurality of heatsink faces 710, 710′, 720, 725, 725′ in accordance with another alternative embodiment of the invention.

### DETAILED DESCRIPTION

Presently disclosed embodiments relate to multi-directional heatsink cooling systems for air cooling of electronic devices such as CPUs, motherboards, graphical cards, or any other sort of electronic device which may take advantage of embodiments disclosed herein. Utilization of embodiments disclosed herein may even be extended to cooling of mechanical or other devices, which may be located in small spaces, to take advantage of improved cooling capabilities as disclosed herein.

According to an aspect of the invention, there is provided a multi-directional heatsink cooling system for cooling a device. The multi-directional heatsink cooling system includes a heatsink base in a first plane. The heatsink base is connected to a device requiring cooling. A plurality of heatsink fins are attached to the heatsink base in a perpendicular or parallel orientation to the first plane. The plurality of heatsink fins are arranged to accept external cooling in multiple directions. A plurality of heat pipes extend through the plurality of heatsink fins. The plurality of heat pipes are connected to the heatsink base. Two or more air diverters are also present, with each air diverter associated with cooling the plurality of heatsink fins in a single path of a plurality of air paths. Each air path is associated with exactly one of the multiple directions of the heatsink fins, in order to cool the plurality of heatsink fins. A general technical advantage is provided of improved cooling of heatsink fins, on an on-demand basis allowing increased cooling, if necessary (such as when over-clocking a CPU, or when a server CPU has significant client-scheduled workload/demand changes).

According to an alternative aspect of the invention, there is provided a multi-directional heatsink cooling system for cooling a device. The multi-directional heatsink cooling system includes a heatsink base in a first plane. The heatsink base is connected to a device requiring cooling. A plurality of heatsink fins are attached to the heatsink base in a perpendicular or parallel orientation to the first plane, the plurality of heatsink fins arranged to accept external cooling in multiple directions. A plurality of heat pipes extend through the plurality of heatsink fins. The plurality of heat pipes are connected to the heatsink base. Two or more air diverters are also present, with each air diverter associated with cooling the plurality of heatsink fins in a single path of a plurality of air paths. Each air path is associated with exactly one of the multiple directions of the heatsink fins, in order to cool the plurality of heatsink fins. Each of the heatsink fins is formed such that a plenum is present in each of the heatsink fins and when the plurality of heatsink fins are stacked a greater plenum is formed via a conjunction of the plenum present in each of the plenums present in each of the plurality of heatsink fins. The greater plenum allows air directed along each air path to exit the plurality of heatsink fins via the greater plenum and thereby cool the plurality of heatsink fins, and provide advantages in cooling. A general technical advantage is improved cooling of heatsink fins, on an on-demand basis allowing increased cooling, if necessary (such as when over-clocking a CPU, or other times of increased CPU demand), and improved airflow in cooling.

According to an alternative aspect of the invention, there is provided a multi-directional heatsink cooling system for cooling a device. The multi-directional heatsink cooling system includes a heatsink base in a first plane. The heatsink base is connected to a device requiring cooling. A plurality of heatsink fins are attached to the heatsink base in a perpendicular or parallel orientation to the first plane, the plurality of heatsink fins arranged to accept external cooling in multiple directions. A plurality of heat pipes extend through the plurality of heatsink fins. The plurality of heat pipes are connected to the heatsink base. Two or more air diverters are also present, with each air diverter associated with cooling the plurality of heatsink fins in a single path of a plurality of air paths. Each air path is associated with exactly one of the multiple directions of the heatsink fins, in order to cool the plurality of heatsink fins. The plurality of heatsink fins are formed in two or more different shapes to allow the plurality of heatsink fins to separate air from different air pats in order to enhance cooling of the heatsink fins. A general technical advantage is improved cooling of heatsink fins, on an on-demand basis allowing increased cooling, if necessary (such as when over-clocking a CPU, or other times of increased demand), and improved airflow in cooling via the different shaped heatsink fins.

According to some embodiments of the invention, one or more cooling fans are associated with each air path of the plurality of air paths. A general technical advantage for this optional feature includes separate fans and associated cooling for each air path allowing for more customized control.

According to some embodiments of the invention, also included are two or more cooling fans, the two or more cooling fans including a first cooling fan and a second cooling fan. The first cooling fan is engaged to cool the multi-directional heatsink at all times via a first air path. The second cooling fan is engaged to cool the multi-directional heatsink upon an increased cooling demand via a second air path. A general technical advantage for this optional feature includes customized control of cooling of multi-directional heatsink upon increased demand or lessened demand.

According to some embodiments of the invention, the second cooling fan is engaged by an algorithmic control model. A general technical advantage for this optional feature is customizable and precise controls for cooling by the second cooling fan.

According to some embodiments of the invention, the device requiring cooling is an electronic device. A general technical advantage for this optional feature is improved performance and longevity of the electronic device.

According to some embodiments of the invention, the device requiring cooling is a motherboard or a graphical card. A general technical advantage for this optional feature is improved performance and longevity of the motherboard and graphical card.

According to some embodiments of the invention, the plurality of heatsink fins are stacked parallel to one another in a single plane. A general technical advantage for this optional feature is improved cooling performance of the plurality of heatsink fins.

According to some embodiments of the invention, the plurality of heatsink fins are stacked via one or more stacking features molded into each heatsink fin of the plurality of heatsink fins. A general technical advantage for this optional feature is improved stability and durability of the multi-directional heatsink, as well as improved airflow via a controlled gap between heatsink fins to provide for increased airflow and correspondingly increased cooling.

According to some embodiments of the invention, the plurality of heatsink fins are perforated with a plurality of apertures, and one or more of the apertures provide for heat pipes to extend through the plurality of heatsink fins. A general technical advantage for this optional feature is improved conducting of heat through the heat pipes and the multi-directional heatsink.

According to some embodiments of the invention, the heat pipes are soldered or brazed to the heatsink fins and the heatsink base. A general technical advantage for this optional feature is improved conduction of heat via heat pipes and improved stability of the multi-directional heatsink.

According to some embodiments of the invention, the heatsink base, the plurality of heatsink fins, and the heat pipes are bonded via a heating process. A general technical advantage for this optional feature is improved stability of the multi-directional heatsink by the bonding, and improve heat conducting.

According to some embodiments of the invention, one or more vents are formed in one or more heatsink fins, the one or more vents allowing ingress of air into the heatsink fins and the plenum from one or more air paths in order to enhance cooling of the heatsink fins. The provides for the advantage of further cooling of heatsink fins via increased air flow.

According to some embodiments of the invention, a portion of air directed along the first air path and the second air path exits the multi-directional heatsink via the greater plenum, thereby cooling the multi-directional heatsink. This provides for reducing turbulence of airflow associated with the air paths, and thereby improved cooling.

According to some embodiments of the invention, a portion of air directed along the first air path and the second air path exits the multi-directional heatsink via two or more greater plenums. This provides for reducing turbulence of airflow associated with the air paths, and thereby improved cooling.

According to some embodiments of the invention, the one or more heatsinks form a plenum allowing air to ingress or egress the plurality of heatsink fins and thereby enhance cooling of the plurality of heatsink fins. This provides further advantages in improved cooling.

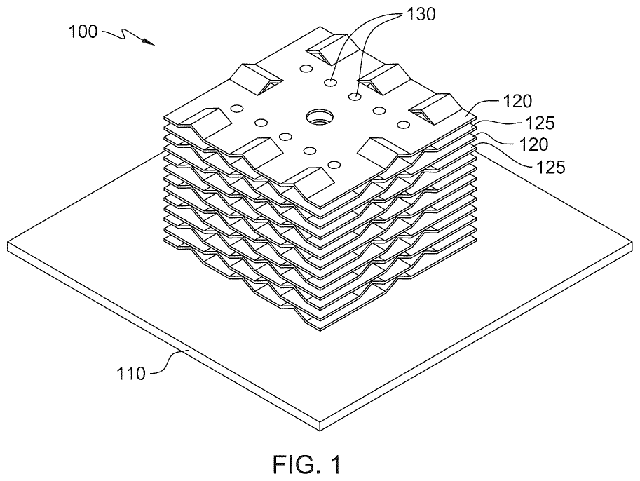

FIG. 1 is a perspective diagram of a multi-directional heatsink 100, in accordance with an embodiment of the present invention. Displayed 100 is the multi-directional heatsink. Multi-directional heatsink 100 is shown as attached to heatsink base 110 in a first plane. The heatsink base 110 is, in turn attached to a device requiring cooling, such as a motherboard, graphical card, or other type of electronic device requiring cooling (not shown in FIG. 1). In alternative embodiments of the invention, the device requiring cooling may be a mechanical or other type of device (not displayed). A plurality of stacked heatsink fins 120, 125 are displayed in connection with multi-directional heatsink 100. As displayed in FIG. 1, the stacked heatsink fins 120, 125 are stacked parallel to one another in a single plane, but other configurations are contemplated within embodiments of the invention. The plurality of heatsink fins 120, 125 are attached to form a stacked formation, which is attached to heatsink base 110. In an embodiment of the invention, such as displayed in connection with FIG. 1, stacked formation of the plurality of heatsink fins 120, 125 may be attached via stacking features 120, 125. A plurality of heat pipes extend through the heatsink fin apertures 130 and are connected to the heatsink base 110. In various embodiments of the invention, heat pipes may be soldered or brazed to heatsink fins 120, 125 (or connected via another heating process). Heat pipes may be formed of any sort of metal or other material, in order provide for conduction of heat from heatsink base 110 in facilitation of cooling of heatsink base 110. In various embodiment of the invention, heatsink fins 120, 125 may be attached to heatsink base 110 in a perpendicular or parallel orientation to the first plane associated with the heatsink base 110 (with a parallel formation displayed in FIG. 1 et seq.), with other orientations specifically contemplated as within the scope of the embodiments disclosed herein. Heatsink fins 120, 125 in various embodiments may be composed of aluminum, steel, copper, titanium, or any metallic, ceramic, or other material to allow conduction of heat away from heatsink base 110 and, in turn, the electronic device requiring cooling. Heatsink fins 120, 125, in various embodiments of the invention, accept cooling in multiple directions from cooling fans along air paths (not displayed here).

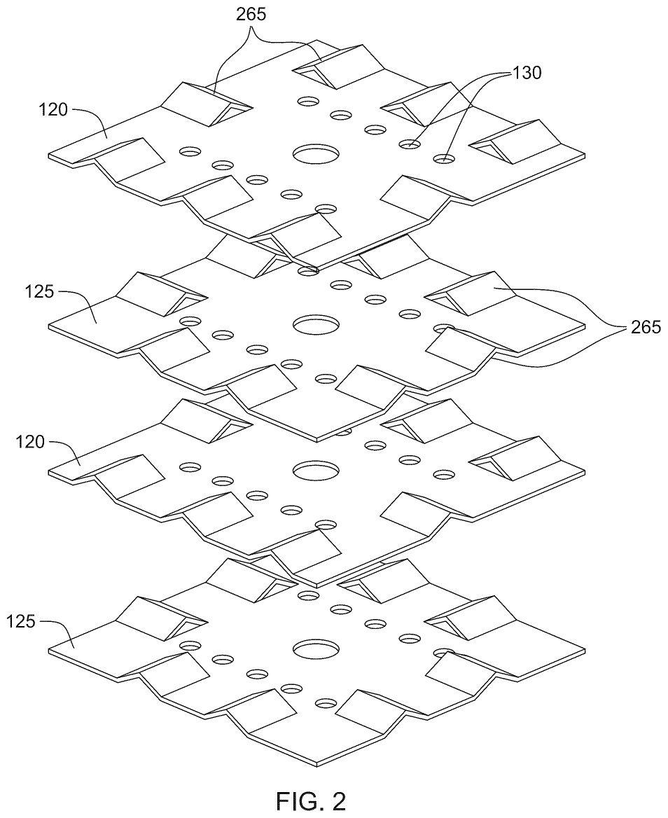

FIG. 2 displays an exploded view of a plurality of heatsink fins 120, 125 in accordance with an embodiment of the invention. In an embodiment such as displayed in connection with FIG. 2, multiple heatsink fins 120, 125 are stacked via stacking features 265 molded or stamped during manufacture into each heatsink fin 120, 125. In an embodiment of the invention, heatsink fins 120, 125 are of two different, alternating types allowing stacking features 265 to fit together precisely. Stacking features 265 provide for heatsink fins 120, 125 to be stacked, while still allowing air to pass through the heatsink fins 120, 125. Heatsink fins 120, 125 each are formed to have heatsink fin apertures 130 present in any number. Heatsink fin apertures 130 provide access through which heat pipes extend, providing for further conduction of heat from heatsink base 110 (not displayed in FIG. 2).

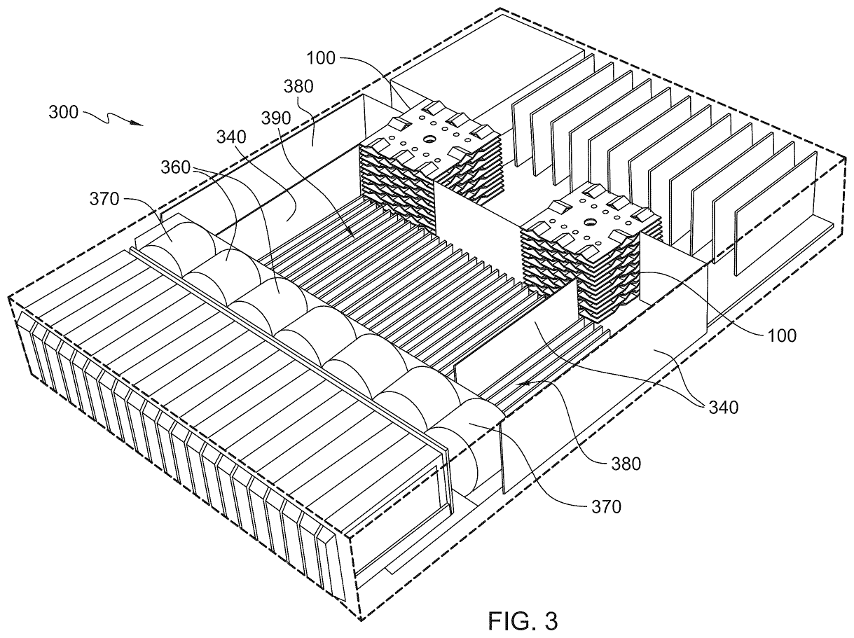

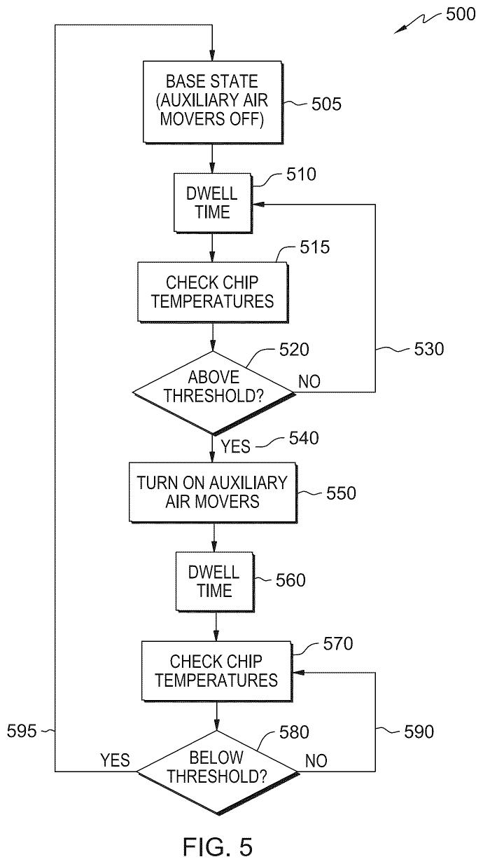

FIG. 3 displays a perspective diagram of an electronic device 300 with installed multi-directional heatsinks 100, in accordance with an embodiment of the invention. Electronic device 300 may be, in various embodiments of the invention, a computer motherboard, a graphics card, or any other sort of electronic device 300 in need of cooling. Multi-directional heatsinks 100 are installed into electronic device 300. Heatsink bases 110 (not displayed in FIG. 3) of multi-directional heatsinks 100 are in direct contact with components of electronic device 300 in need of cooling. Displayed in FIG. 3 are also a plurality of cooling fans 360, 370. Cooling fans 360, 370 in various embodiments of the invention, may function based on alternating current or direct current. Cooling fans 360, 370 in an embodiment of the invention such as displayed in FIG. 3 may be situated along different air paths 380, 390. Air diverters 340 confirm that air pushed by cooling fans 360, 370 travels along a single air path (of air paths 380, 390), and contacts a direction of multiple directions of the multi-directional heatsinks 100. Each air path 380, 390 may be associated with one or more cooling fans 360, 370. As further discussed in connection with FIG. 5, cooling fans 360, 370 along different air path(s) 380, 390 may be turned on and off at different times by a microprocessor control system (not displayed) in order to best cool multi-directional heatsinks 100, and thereby cool attached electronic device 300. In various embodiments of the invention, microprocessor control system may rely upon one or more sensors determining current chip temperature, average chip temperature, total server airflow rate, total server pressure drop, and/or local pressure drop in determining when to enact enhanced cooling activity, as discussed herein. Further details regarding microprocessor control system, with regard to an embodiment of the invention, are also discussed below.

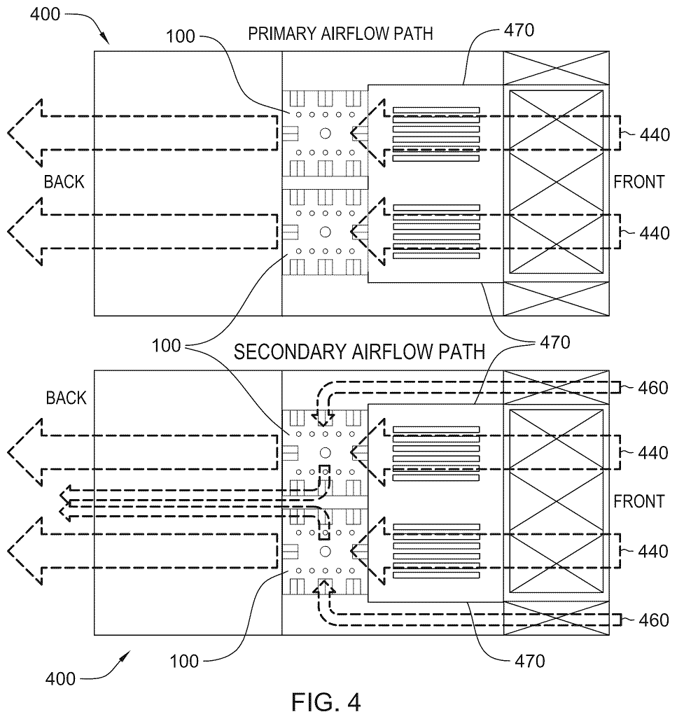

FIG. 4 displays a schematic diagram of an electronic device 400 with installed multi-directional heatsinks 100 cooled by airpaths 440, 460, in accordance with an embodiment of the present invention. Airpath 440 indicates a path of air pushed by one or more fans. Airpath 460 is indicates a different path of air pushed by one or more different fans. Air diverters 470 displayed in FIG. 4 confirm that air pushed along different air paths 440, 460 cools different directions associated with multi-directional heatsinks 100. In an embodiment of the invention, airpath 440 is a primary airpath which is engaged to cool a direction of multi-directional heatsink at all times (i.e., with fan engaged at all time). Airpath 460 is a secondary airpath, which is engaged to cool a different direction of multi-directional heatsink, with fans associated with airpath 460 engaged according to a demand basis by microprocessor control system (not displayed). Decisions made by microprocessor control system as to powering of fans in airpaths 440, 460 are further discussed in connection with FIG. 5.

FIG. 5 displays a flowchart 500 showing temperature control of fans in secondary airpath, in accordance with an embodiment of the invention. In various embodiments of the invention, a microprocessor control system (or the equivalent) makes decisions as to when to turn on and turn off fans associated with secondary air path, to effect enhanced cooling of multi-directional heatsink 100. Microprocessor control system begins at base state 505, commanding auxiliary air movers (associated with secondary airpath) to be off. Microprocessor control system at step 510 waits for a period of time before performing any actions (“dwell time”). At step 515, microprocessor control system checks the current temperature of microprocessor. At step 520, microprocessor control system determines whether the current temperature of the microprocessor is above a threshold (above, for example 65° C.). In various embodiments of the invention, sensors may be located directly on the microprocessor, on multi-directional heatsink 100, or otherwise. If not at step 530, microprocessor control system returns to dwell state 510. If yes at step 540, microprocessor control system turns on auxiliary air movers (associated with secondary airpath) 550. At step 560, microprocessor control system again waits for a period of time before performing any actions. At step 570, microprocessor control system again checks chip temperature directly, or via testing of multi-directional heatsink 100. At step 580, a determination is made of whether chip temperature is now below the threshold. If not at step 590, auxiliary air movers (associated with secondary airpath) continue running to cool multi-directional heatsink and microprocessor. If yes, at step 595 microprocessor control system returns to base state 505 with auxiliary air movers off. In various embodiments of the invention, auxiliary air movers (associated with secondary airpath) may not be off, but rather functioning at a slower speed in base state 505.

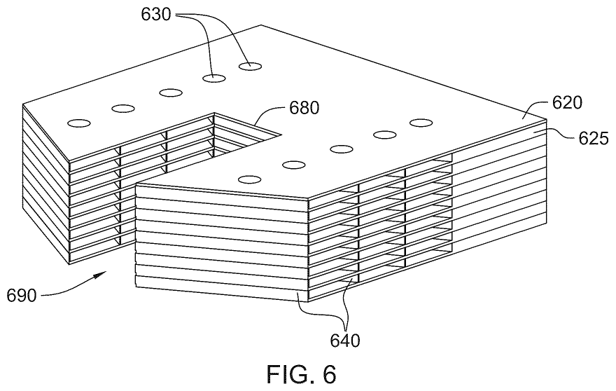

FIG. 6 displays a perspective view of a plurality of heatsink fins 620, 625 in accordance with an alternative embodiment of the invention. In an alternative embodiment such as displayed in connection with FIG. 6, multiple heatsink fins 620, 625 are stacked in a fashion to allow air to pass through heatsink fins 620, 625 to allow sufficient cooling. Heatsink fins 620, 625, in an embodiment of the invention, may be stacked via lining up of stacking features (not displayed here), or in another way which provides for heatsink fins 620, 625 to be formed into a unified structure sufficient for cooling of all of heatsink fins 620, 625 and an attached device (not displayed in connection with FIG. 6). Heatsink fin apertures 630 are present in any number in each heatsink fin 620, 625 to provide for heat pipes to extend through heatsink fins 620, 625, and provide for further conduction of heat from heatsink base 110 (not displayed in FIG. 6). In an embodiment such as displayed in connection with FIG. 6, each heatsink fin 620, 625 is formed that a plenum 680 is present in each of the heatsink fins 620, 625 and when the plurality of heatsink fins 620, 625 are stacked, a “greater plenum” 690 is formed via a conjunction of plenums 680. Greater plenum 690 allows air directed from one or more air paths (discussed in connection with other figures) to enter heatsink fins 620, 625 at one direction but exit at the greater plenum 690 and thereby cool the plurality of heatsink fins 620, 625 in an efficient manner by reducing impedance of multiple air streams meeting and exiting from heatsink fins 620, 625. In an embodiment of the invention, heatsink fins 620, 625 are formed such that one or more vents 640 are present in each heatsink fin 620, 625, the one or more vents 640 allowing ingress of air into the heatsink fins 620, 625 and the plenum 690 from one or more air paths, in order to enhance cooling of the heatsink fins 620, 625.

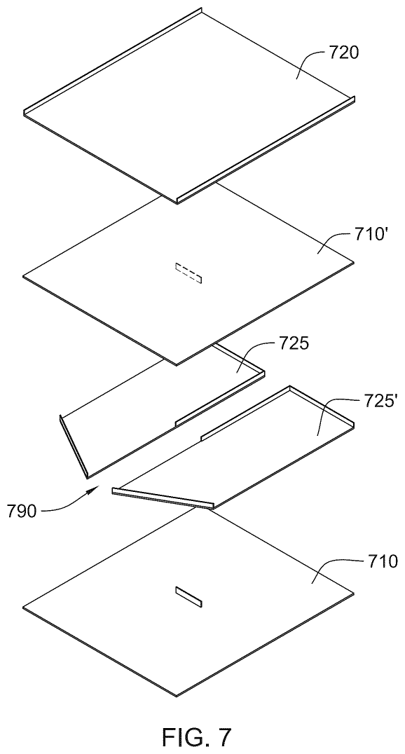

FIG. 7 displays an exploded view of a plurality of heatsink fins 710, 710′, 720, 725, 725′ in accordance with another alternative embodiment of the invention. In another alternative embodiment, such as displayed in connection with FIG. 7, multiple heatsink fins 710, 710′, 720, 725, 725′ are again stacked in a fashion to allow air to pass through heatsink fins 710, 710′, 720, 725, 725′ to allow sufficient cooling. Heatsink fin apertures (not shown) may be present in any in each heatsink fin 710, 710′, 720, 725, 725′ to provide for heat pipes to extend through heatsink fins 710, 710′, 720, 725, 725′, and provide for further conduction of heat from heatsink base 110 (not displayed in FIG. 7). In an embodiment such as displayed in connection with FIG. 7, two or more of heatsink fins 710, 710′, 720, 725, 725′ may be formed in two or more different shapes to allow the plurality of heatsink fins to separate air from different air paths in order to enhance cooling of the heatsink fins 710, 710′, 720, 725, 725′, and thereby cool them in an efficient manner by reducing turbulence of multiple air streams meeting inside of heatsink fins 710, 710′, 720, 725, 725′. Although as displayed in FIG. 7, a certain order of heatsink fins 710, 710′, 720, 725, 725′ is displayed, in various embodiments of the invention, heatsink fins 710, 710′, 720, 725, 725′ may be present in any order, some may be absent and some present, some duplicated, etc., while all are contemplated as within the scope of the invention. In an embodiment of the invention, one or more of heatsink fins 710, 710′, 720, 725, 725′ to form a plenum further allowing air to ingress or egress the plurality of heatsink fins 710, 710′, 720, 725, 725′ and thereby enhance cooling of the plurality of the heatsink fins 710, 710′, 720, 725, 725′.

Based on the foregoing, various embodiments of a multi-directional heatsink cooling system have been disclosed. However, numerous modifications and substitutions can be made without deviating from the scope of the present invention. Therefore, the present invention has been disclosed by way of example and not limitation.

What is claimed is:

1. A multi-directional heatsink cooling system for cooling a device, the multi-directional heatsink cooling system comprising:
a heatsink base in a first plane, the heatsink base connected to a device requiring cooling;
a plurality of heatsink fins attached to the heatsink base in a perpendicular or parallel orientation to the first plane, the plurality of heatsink fins arranged to accept external cooling in multiple directions;
a plurality of heat pipes extending through the plurality of heatsink fins, the plurality of heat pipes connected to the heatsink base; and
two or more air diverters, each air diverter associated with cooling the plurality of heatsink fins in a single air path of a plurality of air paths, each air path associated with exactly one of the multiple directions of the heatsink fins and thereby cool the plurality of heatsink fins.

2. The multi-directional heatsink cooling system of claim 1, wherein one or more cooling fans are associated with each air path of the plurality of air paths.

3. The multi-directional heatsink cooling system of claim 1, further comprising two or more cooling fans, the two or more cooling fans including a first cooling fan and a second cooling fan, the first cooling fan engaged to cool the multi-directional heatsink at all times via a first air path, and the second cooling fan engaged to cool the multi-directional heatsink upon an increased cooling demand via a second air path.

4. The multi-directional heatsink cooling system of claim 3, wherein the second cooling fan is engaged by an algorithmic control module.

5. The multi-directional heatsink cooling system of claim 1, wherein the device requiring cooling is an electronic device.

6. The multi-directional heatsink cooling system of claim 1, wherein the device requiring cooling is a motherboard or a graphical card.

7. The multi-directional heatsink cooling system of claim 1, wherein the plurality of heatsink fins are stacked parallel to one another in a single plane.

8. The multi-directional heatsink cooling system of claim 7, wherein the plurality of heatsink fins are stacked via one or more stacking features molded into each heatsink fin of the plurality of heatsink fins.

9. The multi-directional heatsink cooling system of claim 1, wherein the plurality of heatsink fins are perforated with a plurality of apertures, and one or more of the apertures provide for the heat pipes to extend through the plurality of heatsink fins.

10. The multi-directional heatsink cooling system of claim 9, wherein the heat pipes are soldered or brazed to the heatsink fins and the heatsink base.

11. The multi-directional heatsink cooling system of claim 1, wherein the heatsink base, the plurality of heatsink fins, and the heat pipes are bonded via a heating process.

12. A multi-directional heatsink cooling system for cooling a device, the multi-directional heatsink comprising:
a heatsink base in a first plane, the heatsink base connected to a device requiring cooling;
a plurality of heatsink fins attached to the heatsink base in a perpendicular or parallel orientation to the first plane, the plurality of heatsink fins arranged to accept external cooling in multiple directions;
a plurality of heat pipes extending through the plurality of heatsink fins, the plurality of heat pipes connected to the heatsink base; and
two or more air diverters, each air diverter associated with cooling the plurality of heatsink fins in a single air path of a plurality of air paths, each air path associated with exactly one of the multiple directions of the heatsink fins,
wherein each of the plurality of heatsink fins is formed such that a plenum is present in each of the heatsink fins and when the plurality of heatsink fins are stacked a greater plenum is formed via conjunction of the plenums present in each of the plurality of heatsink fins, the greater plenum allowing air directed along each air path to exit the plurality of heatsink fins via the greater plenum and thereby cool the plurality of heatsink fins.

13. The multi-directional heatsink cooling system of claim 12, further comprising one or more vents formed in one or more heatsink fins, the one or more vents allowing ingress of air into the heatsink fins and the plenum from one or more air paths in order to enhance cooling of the heatsink fins.

14. The multi-directional heatsink cooling system of claim 13, further comprising two or more cooling fans, the two or more cooling fans including a first cooling fan and a second cooling fan, the first cooling fan engaged to cool the multi-directional heatsink at all times via a first air path, and the second cooling fan engaged to cool the multi-directional heatsink upon an increased cooling demand via a second air path.

15. The multi-directional heatsink cooling system of claim 14, wherein the second cooling fan is engaged by an algorithmic control module.

16. The multi-directional heatsink cooling system of claim 12, wherein the device requiring cooling is an electronic device.

17. The multi-directional heatsink cooling system of claim 12, wherein the device requiring cooling is a motherboard or a graphical card.

18. The multi-directional heatsink cooling system of claim 14, wherein a portion of air directed along the first air path and the second air path exits the multi-directional heatsink via the greater plenum, thereby cooling the multi-directional heatsink.

19. A multi-directional heatsink cooling system for cooling a device, the multi-directional heatsink comprising:
a heatsink base in a first plane, the heatsink base connected to a device requiring cooling;
a plurality of heatsink fins attached to the heatsink base in a perpendicular or parallel orientation to the first plane, the plurality of heatsink fins arranged to accept external cooling in multiple directions;
a plurality of heat pipes extending through the plurality of heatsink fins, the plurality of heat pipes connected to the heatsink base; and
two or more air diverters, each air diverter associated with cooling the plurality of heatsink fins in a single air path of a plurality of air paths, each air path associated with exactly one of the multiple directions,
wherein the plurality of heatsink fins are formed in two or more different shapes to allow the plurality of heatsink fins to separate air from different air paths in order to enhance cooling of the heatsink fins.

20. The multi-directional heatsink cooling system of claim 19, wherein one or more cooling fans are associated with each air path of the plurality of air paths.

21. The multi-directional heatsink cooling system of claim 19, further comprising two or more cooling fans, the two or more cooling fans including a first cooling fan and a second cooling fan, the first cooling fan engaged to cool the multi-directional heatsink at all times via a first air path, and the second cooling fan engaged to cool the multi-directional heatsink upon an increased cooling demand via a second air path.

22. The multi-directional heatsink cooling system of claim 21, wherein the second cooling fan is engaged by an algorithmic control module.

23. The multi-directional heatsink cooling system of claim 19, wherein the device requiring cooling is an electronic device.

24. The multi-directional heatsink cooling system of claim 19, wherein the device requiring cooling is a motherboard or a graphical card.

25. The multi-directional heatsink cooling system of claim 19, wherein one or more heatsink fins form a plenum allowing air to ingress or egress the plurality of heatsink fins and thereby enhance cooling of the plurality of heatsink fins.
